(19) United States
(12) Patent Application Publication
(10) Pub. No.: US 2025/0148160 A1
(43) Pub. Date: May 8, 2025

(54) Method for extracting harmonic response of offshore wind power

(71) Applicant: Shanghai Investigation, Design & Research Institute Co., Ltd., Shanghai (CN)

(72) Inventors: Mingqiang XU, Shanghai (CN); Huiyuan TIAN, Shanghai (CN); Li CHEN, Shanghai (CN); Haifeng CHENG, Shanghai (CN); Juan JIANG, Shanghai (CN); Zeyun YANG, Shanghai (CN); Xu CHEN, Shanghai (CN)

(73) Assignee: Shanghai Investigation, Design & Research Institute Co., Ltd., Shanghai (CN)

(21) Appl. No.: 18/623,072

(22) Filed: Apr. 1, 2024

(30) Foreign Application Priority Data
Aug. 2, 2023 (CN) 2023109706137

(51) Int. Cl. G06F 30/20

(52) U.S. Cl. CPC G06F 30/20

(57) ABSTRACT

A method for extracting harmonic response from offshore wind turbine structure, including: F1, continuously collecting its acceleration response under non-operating conditions, obtaining the acceleration response signal of the tower under only environmental load, and cropping all collected signals into signal segments with a length of L; F2, using Fourier transform to convert all signal segments from the time domain to the frequency domain, obtaining the frequency spectrum of the signal P; F3, according to the maximum rotational speed P, either designed or recorded by the SCADA system, determining the maximum harmonic response frequency Fₘₐₓ=N×P, 1≤N≤12 to be extracted, and cropping the individual frequency spectrum into three segments P₁, P₂, P₃, corresponding to frequency ranges of 0˜F₁, F₁˜F₂, F₂˜F₃, where the selected frequency F₁ is not less than Fₘₐₓ; F4, cropping all frequency spectra according to F3 to form a frequency spectral dataset D without harmonic excitation effects.

### FIELD OF THE INVENTION

The present disclosure relates to the field of wind turbine monitoring technology, specifically relates to a method for extracting the harmonic response of offshore wind turbine.

### BACKGROUND OF THE INVENTION

The tower section of offshore wind turbine structures plays a role in supporting the wind turbine unit and absorbing the vibration energy of the wind turbine unit. To achieve stable and reliable wind power generation, the wind turbine tower regularly supports the wind turbine unit at a height of 60 meters, sometimes even more than 100 meters, at a cost accounting for approximately 15% of the total operation cost. During the operation of the wind turbine, the wind turbine tower is often exposed to extreme wind environments. Herein large deflection deformation and repeated stress cycles can cause damage to the tower. As a supporting component of the wind turbine unit, the tower section often suffers from severe damage leading to catastrophic failure of the wind turbine structure;

The excitation sources of wind turbine tower usually include two parts, namely, environmental loads such as wind, waves, currents, earthquakes, and ice, as well as mechanical transmission loads generated by the wind turbine during power generation (mainly from harmonic loads caused by blade rotation). Under normal operating conditions of the wind turbine, the structural response caused by harmonic loads often accounts for a significant proportion and cannot be ignored. By installing accelerometer sensors on the tower, vibrations of the wind turbine tower caused by the combined effects from environmental and harmonic excitation loads can be captured. Separating the two types of vibration responses from this vibration data is crucial for analyzing the excitation sources of the wind turbine tower, evaluating the advantages and disadvantages of offshore wind turbine foundation structure designs, monitoring wind turbine unit failures, and implementing effective vibration control measures;

Traditional time-varying signal decomposition methods, such as wavelet transform, Hilbert-Huang transform, and variational mode decomposition, can achieve the extraction of signal components. However, these methods have the following shortcomings:
(1) When the energy of harmonic excitation is small, it is easy to be ignored as noise;
(2) When the harmonic frequency is extremely close to the actual structural frequency, these methods cannot effectively separate the harmonic frequency from the actual structural frequency.
(3) These methods are purely data-driven and cannot effectively utilize known physical information (such as the rotational frequency monitored by the wind turbine Supervisory Control And Data Acquisition (SCADA) system) for component extraction.

### SUMMARY OF THE INVENTION

The present disclosure provides a method for extracting harmonic responses of offshore wind turbines. In response to resonance interference, the method is proposed to effectively extract harmonic excitation, and even when the harmonic frequency is extremely close to the actual structural frequency, their effective separation can also be achieved.

This application addresses one of the issues in the existing art.

The technical solution adopted by this invention is as follows: to achieve the above objective and other related objectives, the present disclosure provides a method for extracting structural harmonic responses of offshore wind turbines.

A method for extracting the harmonic response of offshore wind turbine, including the following steps:

### Step 1:

Sub-step F1, continuously collecting the acceleration response to a single offshore wind turbine structure in a non-operational state, obtaining the acceleration response signal of the tower only under environmental loads, and trimming all collected signals S into segments of length L;
Sub-step F2, using Fourier transform to convert all signal segments from time domain to frequency domain, and obtaining the frequency spectrum P of the signals;
Sub-step F3, based on the maximum design rotational speed Pₘₐₓ of the wind turbine or the maximum rotational speed Pₘₐₓ of the wind turbine recorded by the wind turbine SCADA system, determining the maximum harmonic response frequency to be extracted: Fₘₐₓ=N×Pₘₐₓ, 3≤N≤12, and dividing the single spectrum into three segments P₁, P₂, P₃ with corresponding frequency ranges of 0˜F₁, F₁˜F₂, F₂˜F₃, among which the selected frequency F₁ is not less than Fₘₐₓ; and
joining segments P₁ and P₂ to form a spectrum P₁₂ with corresponding frequency band range 0˜F₂;
Or dividing the signal spectrum into two segments, the segment 0˜F₁ for the part that may be affected by harmonics, and the segment F₁˜F₃ for the part not affected by harmonics. However, due to the generally high sampling frequency of an actual wind turbine, for example, when the sampling frequency is 20 Hz, the corresponding frequency spectrum range is 0-10 Hz, and the maximum harmonic frequency 12Pₘₐₓ of interest may be less than 4 Hz. In order to save computational resources, we divide an additional segment F₂, the segment F₁˜F₂ is for the response prediction of deep learning, while the segment F₂˜F₃ can be discarded. To ensure that P₂ and P₃ contain very few harmonic excitation effects, less than 1% can be considered satisfactory.
Sub-step F4, cropping and splicing all frequency spectra according to F3 procedures to form a frequency spectral dataset D without harmonic excitation effects.

The method disclosed by the present disclosure for extracting harmonic response of offshore wind turbine, also includes the following technical features:
preferably, Step 2: selecting a deep generative model, using the frequency spectral dataset D as the training dataset for the deep generative model, training the deep generative model to be able to autonomously generate several frequency spectra without harmonic excitation effects, corresponding to the frequency band range 0˜F₂. The trained model can autonomously generate several frequency spectra, which is the capability of the deep generative model.
preferably, Step 3: sub-step T1, collecting the acceleration response of a single offshore wind turbine structure under a normal operation state by using the installed acceleration sensor, with the total length of the collected signal being at least L, and cropping the collected signal into signal segments \tilde{S} with the length of L, where the signal segment \tilde{S} represents the acceleration response signal of the tower under the combined action of environmental loads such as wind, waves, plus the harmonic excitation loads;
T2, using Fourier transform to convert the signal segment \tilde{S} from the time domain to the frequency domain, and obtaining the frequency spectrum of the signal \tilde{P};
T3, cropping the frequency spectrum \tilde{P} into \tilde{P}₁, \tilde{P}₂, and \tilde{P}₃ three segments, corresponding to frequency ranges 0˜F₁, F₁˜F₂, F₂˜F₃; At this time, \tilde{P}₂ is the actual or measured value of the frequency spectrum without harmonic excitation effects, because it is greater than 12Pₘₐₓ, and the purpose of the third step is to obtain the measured value.

Preferably, in T3, \tilde{P}₁ contains almost all the harmonic excitation effects, while \tilde{P}₂ and \tilde{P}₃ contain very few harmonic excitation effects. It can be considered that: \tilde{P}₁ contains greater than or equal to 99% of the harmonic excitation effects, while \tilde{P}₂ and \tilde{P}₃ contain less than or equal to 1% of the harmonic excitation effects.

Preferably, in F1, the acceleration sensors are installed from top to bottom on a single wind turbine tower, with a set sampling frequency of 20˜50 Hz, to collect the acceleration response of the wind turbine tower.

Preferably, in F1, the environmental loads include the impact loads of wind and waves applied to the tower.

Preferably, step 4: N1, using the deep generative model trained in the second step, generates a large number of spectra \hat{P}₁₂ without harmonic excitation effects, and cropping them into \hat{P}₁ and \hat{P}₂ two segments, corresponding to frequency ranges 0˜F₁, F₁˜F₂ respectively;
N2, defining the 2-norm of the difference between the frequency spectrum segments \tilde{P}₂ and \hat{P}₂ as the objective function, that is:

$$f ( {\hat{P}}_{12} ) = {‖ {\tilde{P}}_{2} - {\hat{P}}_{2} ‖}_{2} ;$$

selecting one of the frequency spectra \hat{P} that minimizes the objective function ƒ(\hat{P}₁₂) as the optimal generated frequency spectrum \hat{P}^{b};
generating many frequency spectra. Since the model was trained on data without harmonic excitation effects, it can only generate frequency spectra without harmonic excitation effects. Among these frequency spectra, one is the closest to reality, and this optimal spectrum is similar to the actual value \tilde{P}₂ in the F₁˜F₂ frequency band.

Preferably, step 5: S1, splicing the optimal generated frequency spectrum \hat{P}^{b} with \tilde{P}₃, and forming a frequency spectrum P̅ with a frequency range of 0˜F₃;
S2, using Fourier transform to convert P̅ from the frequency domain to the time domain, and generating the signal S̅, where S̅ is the signal component unaffected by harmonic excitation;
S3. extracting the harmonic response Ŝ^{h} from the signal segment \tilde{S} including the harmonic excitation effects, i.e. Ŝ^{h}=\tilde{S}−S̅.

Through the trained deep learning model, it is possible to infer the non-harmonic excitation influence \hat{P}₁ and \hat{P}₂. Since the model is trained on the frequency spectral dataset D of non-harmonic excitation influence, \hat{P}₁ only includes the effects of non-harmonic excitation (such as wind and waves), while \tilde{P}₁ includes both harmonic excitation and wind-wave effects. The difference between the two represents the impact of harmonic excitation, thus achieving the extraction of harmonics response of offshore wind turbine.

During model training, all spectra P₁₂ in the spectral dataset D are used as both input and output of the deep generative model. The standard for completing model training is that the deep generative model can reconstruct all spectra P₁₂ in the spectral dataset D.

The present disclosure has the following beneficial effects:
1. The method disclosed in the present disclosure for extracting the harmonic response of offshore wind turbine based on deep generative model can separate the mixed signals of Gaussian and harmonic responses to obtain the harmonic excitation effects, thus achieving the extraction of harmonic response of offshore wind turbine.
2. The present disclosure constructs a well-trained deep learning model by using the spectral dataset D of non-harmonic excitation influence, collects spectrum segments including harmonic excitation and wind-wave effects, and obtains the signal components affected by harmonic excitation. Using the spectrum segments without harmonic excitation effects (such as wind and waves) of the deep learning model, the optimal generated spectrum is obtained through the objective function. After concatenating the optimal generated spectrum with the spectrum affected by non-harmonic excitation and performing Fourier transform, the signal components without harmonic excitation effects are obtained. The harmonic response is the difference between the signal components affected by harmonic excitation and non-harmonic excitation.

### BRIEF DESCRIPTION OF DRAWINGS

FIG. 1 shows a simplified model of an offshore wind turbine harmonic response extraction method of the present disclosure;

FIG. 2 shows a Gaussian response chart of the offshore wind turbine harmonic response extraction method of the present disclosure;

FIG. 3 shows a harmonic response chart of the offshore wind power harmonic response extraction method of the present disclosure; and

FIG. 4 shows a data curve of the power spectral density function analyzed from the structural response signal of the offshore wind turbine, applying the harmonic response extraction method of the present disclosure.

### DETAILED DESCRIPTION

The specific embodiments of the present disclosure will be further described in conjunction with the accompanying drawings. These embodiments are only used to illustrate the present disclosure and are not intended to limit the present disclosure.

In the description of the present disclosure, it should be noted that the terms “center,” “longitudinal,” “lateral,” “upper,” “lower,” “front,” “rear,” “left,” “right,” “vertical,” “horizontal,” “top,” “bottom,” “inner,” “outer,” and the like, indicating the orientation or positional relationship are based on the orientation or positional relationship shown in the accompanying drawings, solely for the purpose of facilitating the description of the present disclosure and simplifying the description, rather than indicating or implying that the device or component referred to must have a specific orientation, be constructed and operated in a specific orientation, and therefore should not be understood as limiting the present disclosure. In addition, the terms “first” and “second” are only used for descriptive purposes and should not be understood as indicating or implying relative importance.

In this invention, unless otherwise specified and limited, terms such as “installation”, “connection”, “fixing”, “fastening” should be broadly understood, for example, it can be a fixed connection, a detachable connection, or a monolithic connection; it can be a mechanical connection, or an electrical connection; it can be a direct connection, or an indirect connection through an intermediate medium, and it also can be an internal connection between two components. For those skilled in art, the specific meanings of the above terms in this invention can be understood according to the specific situation.

Furthermore, in the description of the present disclosure, unless otherwise specified, the term “multiple” means two or more.

A method for extracting the harmonic response of offshore wind turbine, including the following steps:

### Step 1:

Sub-step F1, continuously collecting the acceleration response of a single offshore wind turbine structure in a non-operational state, obtaining the acceleration response signal of the tower under environmental-only loads, and trimming all collected signals S into segments of length L.
in sub-step F1, acceleration sensors are installed from top to bottom on a single wind turbine tower, with a set sampling frequency of 20˜50 Hz, to collect the acceleration response of the wind turbine tower.
Sub-step F2, using Fourier transform to convert all signal segments from time domain to frequency domain, and obtaining the frequency spectrum P of the signals;
in sub-step F1, the environmental loads include the impact loads of wind and waves applied to the tower.
Sub-step F3, based on the maximum design rotational speed Pₘₐₓ of the wind turbine or the maximum rotational speed Pₘₐₓ of the wind turbine recorded by the wind turbine SCADA system, determining the maximum harmonic response frequency Fₘₐₓ=N×Pₘₐₓ, 3≤N≤12 to be extracted, and dividing the single spectrum into three segments P₁, P₂, P₃ with corresponding frequency ranges of 0˜F₁, F₁˜F₂, F₂˜F₃, among which the selected frequency F₁ is not less than Fₘₐₓ; joining segments P₁ and P₂ to form a spectrum P₁₂ with corresponding frequency band range 0˜F₂.

Or dividing the signal spectrum into two segments, one segment 0˜F₁ for the part that may be affected by harmonics, and another segment F₁˜F₃ for the part not affected by harmonics. However, due to the generally high sampling frequency of actual wind turbine, for example, when the sampling frequency is 20 Hz, the corresponding frequency spectrum range is 0-10 Hz, and the maximum harmonic frequency 12Pₘₐₓ of interest may be less than 4 Hz. In order to save computational resources, we divide an additional segment F₂, the segment F₁˜F₂ is for the response prediction of deep learning, while the segment F₂˜F₃ can be discarded. To ensure that P₂ and P₃ contain very few harmonic excitation effects, less than 1% can be considered satisfactory.
Sub-step F4, cropping and splicing all frequency spectra according to F3 to form a frequency spectral dataset D without harmonic excitation effects.

During model training, all spectra P₁₂ in the spectral dataset D are used as both input and output of the deep generative model. The standard for completing model training is that the deep generative model can reconstruct all spectra P₁₂ in the spectral dataset D.
Step 2: selecting a deep generative model, using the frequency spectral dataset D as the training dataset for the deep generative model, training the deep generative model to be able to autonomously generate several frequency spectra without harmonic excitation effects, corresponding to the frequency band range 0˜F₂. The trained model can autonomously generate several frequency spectra, which is the capability of the deep generative model.
Step 3: sub-step T1, collecting the acceleration response of a single offshore wind turbine structure under normal operation state by using the installed acceleration sensors, with the total length of the collected signal at least L, and cropping the collected signal into signal segments \tilde{S} with a length of L, where the signal segment \tilde{S} represents the acceleration response signal of the tower under the combined action of environmental loads such as wind, waves, and harmonic excitation loads.
Sub-step T2, using Fourier transform to convert the signal segment \tilde{S} from the time domain to the frequency domain, and obtaining the frequency spectrum of the signal \tilde{P}.
Sub-step T3, cropping the frequency spectrum \tilde{P} into \tilde{P}₁, \tilde{P}₂, and \tilde{P}₃ three segments, corresponding to frequency ranges 0˜F₁, F₁˜F₂, F₂˜F₃.

At this time, \tilde{P}₂ is the actual or measured value of the frequency spectrum without harmonic excitation effects, because it is greater than 12Pₘₐₓ, and the purpose of the third step is to obtain the measured value.
In sub-step T3, \tilde{P}₁ contains almost all harmonic excitation effects, while \tilde{P}₂ and \tilde{P}₃ contain very few harmonic excitation effects. It can be considered that: \tilde{P}₁ contains greater than or equal to 99% of the harmonic excitation effects, while \tilde{P}₂ and \tilde{P}₃ contain less than or equal to 1% of the harmonic excitation effects.
Step 4, sub-step N1, using the deep generative model trained in the second step, generates a large number of spectra \hat{P}₁₂ without harmonic excitation effects and cropping them into \hat{P}₁ and \hat{P}₂ two segments, corresponding to frequency ranges 0˜F₁, F₁˜F₂ respectively.
N2, defining the 2-norm of the difference between the frequency spectrum segments \tilde{P}₂ and \hat{P}₂ as the objective function, that is:

$$f ( {\hat{P}}_{12} ) = {‖ {\tilde{P}}_{2} - {\hat{P}}_{2} ‖}_{2} ;$$

selecting one of the frequency spectra \hat{P} that minimizes the objective function ƒ(\hat{P}₁₂) as the optimal generated frequency spectrum Pb; and
generating many frequency spectra. Since the model was trained on data without harmonic excitation effects, it can only generate frequency spectra without harmonic excitation effects. Among these frequency spectra, one is the closest to reality, and this optimal spectrum is similar to the actual value \tilde{P}₂ in the F₁˜F₂ frequency band.
Step 5: sub-step S1, splicing the optimal generated frequency spectrum \hat{P}^{b} with \tilde{P}₃, and forming a frequency spectrum P̅ with a frequency range of 0˜F₃.
S2, using Fourier transform to convert P̅ from the frequency domain to the time domain, and generating the signal S̅, where S̅ is the signal component unaffected by harmonic excitation; and
S3. extracting the harmonic response Ŝ^{h} from the signal segment \tilde{S} including the harmonic excitation effects, i.e. Ŝ^{h}=\tilde{S}−\tilde{S}.

Through the trained deep learning model, it is possible to infer the non-harmonic excitation influence \hat{P}₁ and \hat{P}₂. Since the model is trained on the frequency spectral dataset D of non-harmonic excitation influence, \hat{P}₁ only includes the effects of non-harmonic excitation (such as wind and waves), while \tilde{P}₁ includes both harmonic excitation and wind-wave effects. The difference between the two represents the impact of harmonic excitation, thus achieving the extraction of harmonics response of offshore wind turbine.

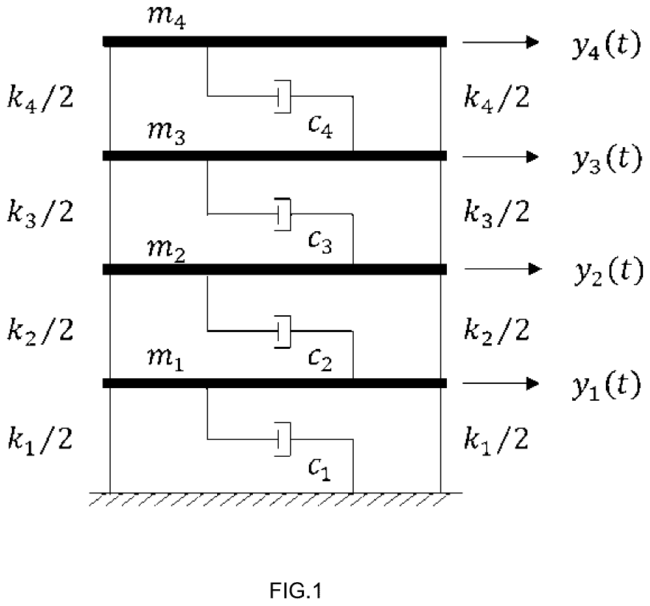

As shown in FIG. 1, a simplified model of a wind turbine, that is a four-degree-of-freedom structure; for example, the masses of all four mass points, m₁, m₂, m₃, and m₄, in the structure totaled to be 10 kg, the stiffness coefficients of all four springs k₁, k₂, k₃, and k₄, are the same at 10,000 N/m, divided in two pieces each at k/2 (5000 N/m) at one side, and the damping coefficients c₁, c₂, c₃, and c₄, of all four dampers are the same at 10N/(m/s). The fourth-order structural frequencies of the structure can be obtained through eigenvalue analysis, which turn out to be 1.7479 Hz, 5.0329 Hz, 7.7109 Hz, and 9.4588 Hz respectively.

Assuming that the initial displacement, velocity, and acceleration of the structure are all 0, at the top of the structure, i.e. m₄, a Gaussian white noise excitation with an amplitude of 0.5N is applied to simulate the influence of environmental excitation. At the same time, a harmonic excitation with frequencies of 1 Hz and 3 Hz is applied to m₄ to simulate the 1P and 3P loads caused by the rotation of the wind turbine blades, with an excitation duration of 90 seconds. To consider the time-varying nature of actual wind turbine tower harmonic excitation, it is assumed that the signal amplitude and frequency are both time-varying, i.e. the harmonic excitation functions y₁(t), y₂(t), y₃(t), and y₄(t) are calculated with:

$$h ( t ) = A [ 0.8 sin ( 2 π ( 1 + 0.01 ( 1 - r ) ) t ) + 1.2 sin ( 2 π ( 3 + 0.01 ( 1 - r ) t ) ) ]$$

where A=0.5 [1+0.1 sin (0.01πt)+0.15 (1−r)] is the time-varying amplitude, t is the time identifier, and r is a Gaussian random number.

The Newmark-beta method is used to calculate the response of the structure under the load, with both the integration time step and the response sampling interval set to 0.01 s. It is assumed that only the vibration acceleration of m4 is measured.

The entire validation process is carried out as follows:
Step 1: In order to form the spectral dataset D without harmonic excitation effects, only Gaussian white noise excitation is applied to the structure, and a total of 5000 random simulations are performed; then, through Fourier transform, the signals obtained from the 5000 simulations are transformed from the time domain to the frequency domain, obtaining the power spectral density function (spectrum), corresponding to a frequency range of 0˜50 Hz. Due to the maximum excitation frequency being 3 Hz, and the maximum structural frequency being 9.4588 Hz, the values of F₁=7 Hz, F₂=10 Hz and F₃=50 Hz are selected, and the power spectrum is divided into three segments P₁, P₂ and P₃ with frequency bands of 0˜F₁, F₁˜F₂, F₂˜F₃.

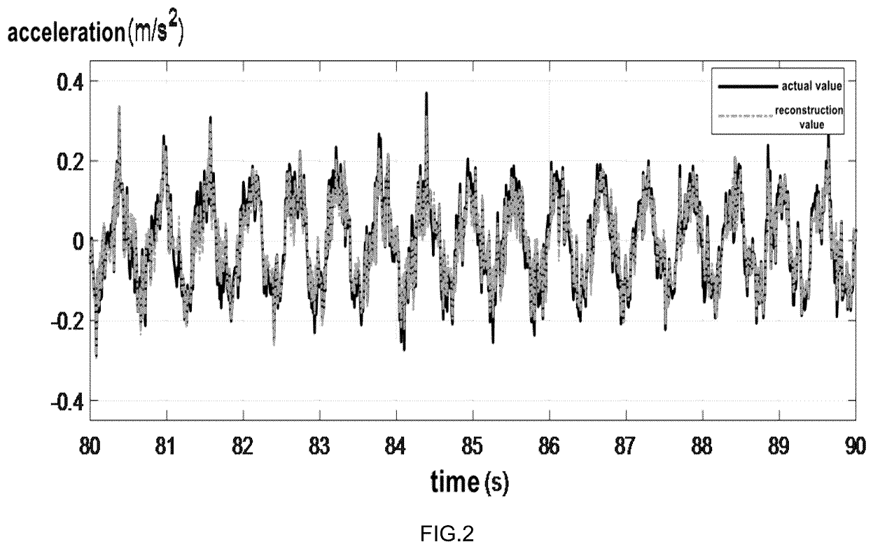

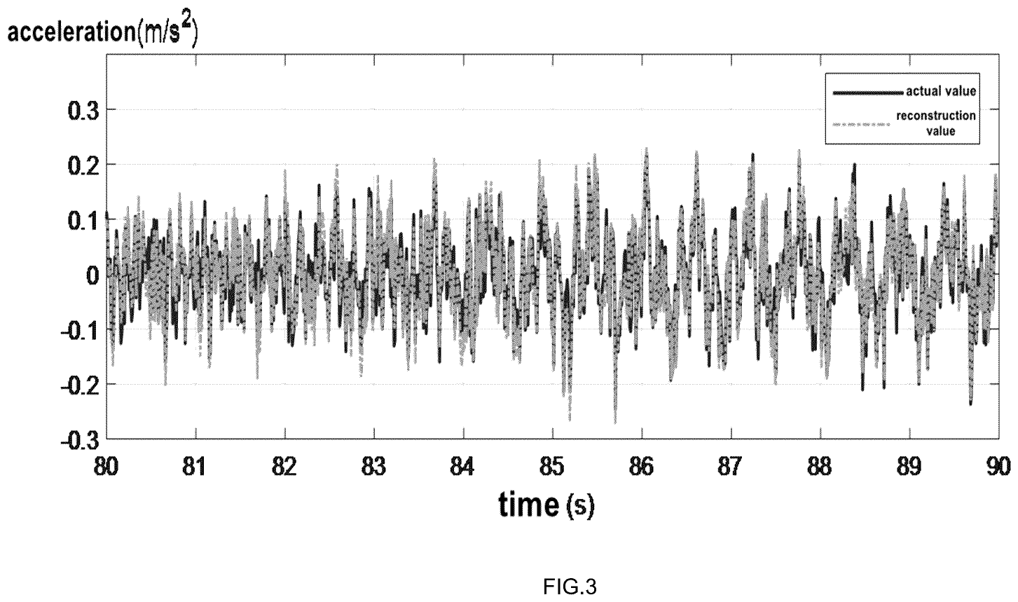

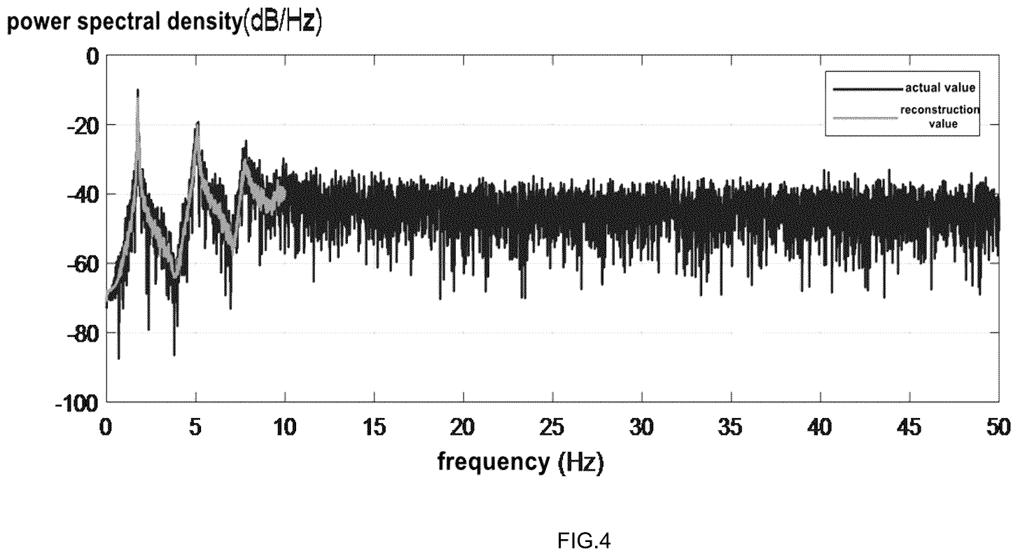

Using a variational autoencoder as a deep generative model, placing the 5000 segments of P₁ and P₂ in the variational autoencoder for training, enabling the model to accurately generate spectra without harmonic excitation effects.
Step 2: Separately implementing Gaussian and harmonic excitation on the model to obtain the real Gaussian response and harmonic response. The Gaussian response in time domain 80˜90 s, shown as actual as the black curve and reconstructed by the deep generative model as dotted curve, in FIG. 2. The harmonic response in time domain of 80-90 s, shown as actual as the black curve and reconstructed by the deep generative model as dotted curve, in FIG. 3.
Step 3: Simultaneously applying Gaussian and harmonic excitation, and converting the structural response signal S into a power spectral density function \tilde{P}, shown as actual as the black curve and reconstructed by the deep generative model as dotted curve, in FIG. 4. The power spectral density function is divided into three segments \tilde{P}₁, \tilde{P}₂ and \tilde{P}₃ corresponding to the frequency bands 0˜F₁, F₁˜F₂, F₂˜F₃. The division is not shown in FIG. 4.

Using the trained variational autoencoder to generate 300 sets of power spectral density functions, and dividing them into 0˜F₁, F₁˜F₂ two segments \hat{P}₁ and \hat{P}₂, comparing the second segments \tilde{P}₂, \tilde{P}₂ of the generated and real power spectral density functions, and selecting one optimal power spectral density function \hat{P}^{b}, as shown by the gray curve in FIG. 4. It can be seen that the generated optimal power spectral density function closely reflects the trend of the real power spectral density function, indicating that the deep generative model can generate responses reflecting the main vibration characteristics of the structure.

Concatenating \hat{P}^{b} and \tilde{P}₃ to form a complete power spectral density function in the 0˜50 Hz frequency band, using the Fourier transform to convert it into the time domain, generating the signal component S̅ without harmonic excitation effects, as shown by the gray curve in FIG. 2. Comparing the two curves in FIG. 2, it indicates that the structural Gaussian response reconstructed by the deep generative model is extremely close to the actual value.

Then, extracting the harmonic response Ŝ^{h} from the signal segment \tilde{S} including the harmonic excitation effects, i.e. Ŝ^{h}=\tilde{S}−S̅, the obtained curve is shown as the gray curve in FIG. 3. It can be seen from the figure that the structural harmonic response reconstructed by the deep generative model is also extremely close to the actual value, indicating that the method for extracting harmonic response of offshore wind turbine based on deep generative model disclosed in the present disclosure can separate the mixed signals of Gaussian and harmonic responses.

The preferred embodiments of the present disclosure are discussed above but is not used to limit the present disclosure. The person skilled in the art can make various amendments or modification to the present disclosure. Any modification, equivalent replacement, improvement, etc. made within the spirit and principle of the present disclosure shall be within the protection scope of the present disclosure.

1. A method for extracting a harmonic response of an offshore wind turbine tower, comprising:
Step 1:
sub-step F1, continuously collecting acceleration responses of a single offshore wind turbine tower in a non-operational state, obtaining acceleration response signals of the turbine tower under only environmental loads, and trimming all collected acceleration response signals S into signal segments of a length L;
sub-step F2, using Fourier transform to convert all signal segments from time domain to frequency domain, and obtaining a frequency spectrum P of the acceleration response signals;
sub-step F3, providing a SCADA (Supervisory Control And Data Acquisition) system, determining a maximum harmonic response frequency Fₘₐₓ=N×Pₘₐₓ, 3≤N≤12 to be extracted, based on a maximum design rotational speed Pₘₐₓ of the wind turbine tower or a maximum rotational speed Pₘₐₓ of the wind turbine tower recorded by the wind turbine SCADA system, and dividing the frequency spectrum into three sub-frequency segments P₁, P₂, P₃ with corresponding frequency ranges of 0˜F₁, F₁˜F₂, F₂˜F₃, wherein F₁ is a selected frequency and F₁ is not less than Fₘₐₓ; joining the sub-frequency segments P₁ and P₂ to form a sub-frequency spectrum P₁₂ with corresponding frequency band range of 0˜F₂; and
sub-step F4, cropping and splicing all frequency spectra according to sub-step F3 to form a frequency spectral dataset D without harmonic excitation effects.

2. The method according to claim 1, further comprising step 2: selecting a deep generative model, using the frequency spectral dataset D as the training dataset for the deep generative model, training the deep generative model to be able to autonomously generate several frequency spectra without harmonic excitation effects, corresponding to the frequency band range 0˜F₂.

3. The method according to claim 2, further comprising step 3, comprising:
sub-step T1, collecting acceleration responses of a single offshore wind turbine structure under normal operation state by using installed acceleration sensors, with the total length of the collected acceleration response signal at least L, and cropping the collected acceleration response signals into signal segments \tilde{S} with the length of L, wherein the signal segment \tilde{S} represents the acceleration response signal of the tower under the combined action of environmental loads such as wind, waves, and harmonic excitation loads;
sub-step T2, performing Fourier transform to convert the signal segment \tilde{S} from the time domain to the frequency domain, and obtaining a frequency spectrum of the signal \tilde{P};
sub-step T3, cropping the frequency spectrum \tilde{P} into three spectra segments \tilde{P}₁, \tilde{P}₂, and \tilde{P}₃, corresponding to frequency ranges 0˜F₁, F₁˜F₂, F₂˜F₃.

4. The method according to claim 3, further comprising step 4, comprising:
sub-step N1, applying the deep generative model trained in the step 2, to generate a large number of spectra \hat{P}₁₂ without harmonic excitation effects, and cropping each of the large number of spectra \hat{P}₁₂ into two frequency spectrum segments \hat{P}₁ and \hat{P}₂, corresponding to frequency ranges 0˜F₁, F₁˜F₂ respectively;
sub-step N2, defining a 2-norm of a difference between the two frequency spectrum segments \tilde{P}₂ and \hat{P}₂ as an objective function:
$$f ( {\hat{P}}_{12} ) = {‖ {\tilde{P}}_{2} - {\hat{P}}_{2} ‖}_{2} ;$$
selecting one of the large number of spectra \hat{P}₁₂ which has a smallest objective function ƒ(\hat{P}₁₂) and defining it as an optimally generated frequency spectrum \hat{P}^{b}.

5. The method according to claim 4, further comprising step 5, comprising:
sub-step S1, splicing the optimally generated frequency spectrum \hat{P}^{b} with \tilde{P}₃, and forming a frequency spectrum P̅ with a frequency range of 0˜F₃;
sub-step S2, performing Fourier transform to convert P̅ from frequency domain to time domain, and generating a signal segment S̅, wherein the signal segment S̅ is a signal component unaffected by harmonic excitation;
sub-step S3, extracting harmonic responses Ŝ^{h} from the signal segment \tilde{S} including the harmonic excitation effects, i.e. Ŝ^{h}=\tilde{S}−S̅.

6. The method according to claim 1, wherein the sub-step F1 comprises acceleration sensors are installed from top to bottom on a single wind turbine tower to collect acceleration responses, at a set sampling frequency in a range of 20˜50 Hz.

7. The method according to claim 6, wherein the environmental loads in the sub-step F1 include impact loads of wind and waves applied to the offshore turbine tower.

8. The method according to claim 2, wherein during model training, all spectra P₁₂ in the frequency spectral dataset D are used as both input and output of the deep generative model, wherein a standard for completing the model training requires the deep generative model reconstruct all of the spectra P₁₂ in the frequency spectral dataset D.

9. The method according to claim 7, wherein in sub-step F4, P₂ and P₃ are satisfactory if they contain less than 1% harmonic excitation effects.

10. The method according to claim 9, wherein in the sub-step T3, \tilde{P}₁ contains greater than or equal to 99% of the harmonic excitation effects, while \tilde{P}₂ and \tilde{P}₃ each contains less than or equal to 1% of the harmonic excitation effects.
